(19) United States
(12) Patent Application Publication
(10) Pub. No.: US 2025/0216413 A1
(43) Pub. Date: Jul. 3, 2025

(54) POSITION FINE-TUNING STRUCTURE

(71) Applicant: CHROMA ATE INC., Taoyuan City (TW)

(72) Inventors: Sheng-Hung WANG, Taoyuan City (TW); Po-Hsiang CHANG, Taoyuan City (TW); Zhe-Min LIAO, Taoyuan City (TW)

(21) Appl. No.: 18/908,848

(22) Filed: Oct. 8, 2024

(30) Foreign Application Priority Data
Dec. 28, 2023 (TW) 112151397

(51) Int. Cl. G01R 1/04

(52) U.S. Cl. CPC G01R 1/0408

(57) ABSTRACT

A position fine-tuning structure includes a first plate, a second plate and a guide slider. A top surface of the first plate is recessed with a first linear groove. A bottom surface of the second plate is recessed with a second linear groove. The bottom surface of the second plate directly covers the top surface of the first plate, so that the second linear groove is orthogonal to and in communication with to the first linear groove. The guide slider includes a first pillar and a second pillar which are overlapped with and orthogonal to each other. The first pillar is parallel to the first linear groove and slidably located within the first linear groove, and the second pillar is parallel to the second linear groove and slidably located within the second linear groove.

### CROSS-REFERENCE TO RELATED APPLICATION

This application claims priority to Taiwan Application Serial Number 112151397, filed Dec. 28, 2023, which is herein incorporated by reference.

### BACKGROUND

### Field of Invention

The present disclosure relates to a fine-tuning structure. More particularly, the present disclosure relates to a position fine-tuning structure.

### Description of Related Art

In general, when testing a device under test (e.g., an IC chip, called DUT hereinafter) on a machine, a testing unit is needed to be accurately aligned with the DUT, otherwise the testing result of the DUT might be inaccurate or the DUT itself might be damaged.

However, the above-mentioned testing unit is not accurately aligned with the DUT, the operating personnel usually needs to perform position fine-tuning through complicated procedures. In addition, because a traditional fixture structure for position fine-tuning is bulky, thus, processing a position fine-tuning procedure using the traditional fixture each time quite consumes labor and time, thereby requiring to be improved.

### SUMMARY

According to some embodiments of the present disclosure, a position fine-tuning structure includes a first plate, a second plate and a guide slider. The first plate is formed with a top surface and a first linear groove recessed on the top surface. The second plate is formed with a bottom surface and a second linear groove recessed on the bottom surface. The bottom surface of the second plate directly covers the top surface of the first plate so that the second linear groove is orthogonal to and in communication with the first linear groove. The guide slider includes a first pillar and a second pillar. The first pillar is overlapped with and orthogonal to the second pillar, and the first pillar is parallel to the first linear groove and slidably located within the first linear groove, and the second pillar is parallel to the second linear groove and slidably located within the second linear groove.

According to some embodiments of the present disclosure, a position fine-tuning structure includes a first plate, a second plate, a guide slider and a pressing member. The first plate is recessed with a first linear groove thereon. The second plate is recessed with a second linear groove thereon. The second plate directly covers the first plate so that the second linear groove is orthogonal to and in communication with the first linear groove. The guide slider is L-shaped or cross-shaped, and the guide slider includes a first pillar and a second pillar. The first pillar is overlapped with and orthogonal to the second pillar and integrally connected to the second pillar. The first pillar is parallel to the first linear groove and slidably located within the first linear groove, and the second pillar is parallel to the second linear groove and slidably located within the second linear groove. the pressing member is connected to the first plate and the second plate for pressing the second plate onto the first plate, and limited the guide slider in the first linear groove and the second linear groove.

Thus, through the construction of the embodiments above, the position fine-tuning structure of this disclosure can choose to install a movable second plate stacked onto the first plate without using a regular rail structure, thereby reducing the overall volume and thickness. Also, through the guide slider of the position fine-tuning structure, the first plate and the second plate which are combined together will not be displaced due to gap problems.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a position fine-tuning structure according to one embodiment of the present disclosure.

FIG. 2 is an exploded view of the position fine-tuning structure of FIG. 1.

FIG. 3 is a cross-sectional view of the position fine-tuning structure viewed along a line AA in FIG. 1.

FIG. 4 is a cross-sectional view of the position fine-tuning structure viewed along a line BB in FIG. 1.

FIG. 5 is an operation schematic view of the position fine-tuning structure of this embodiment.

FIG. 6 is a perspective view of a position fine-tuning structure according to one embodiment of the present disclosure.

FIG. 7 is an exploded view of a first fine nudge module of FIG. 6.

FIG. 8 is an exploded view of a second fine nudge module of FIG. 6.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

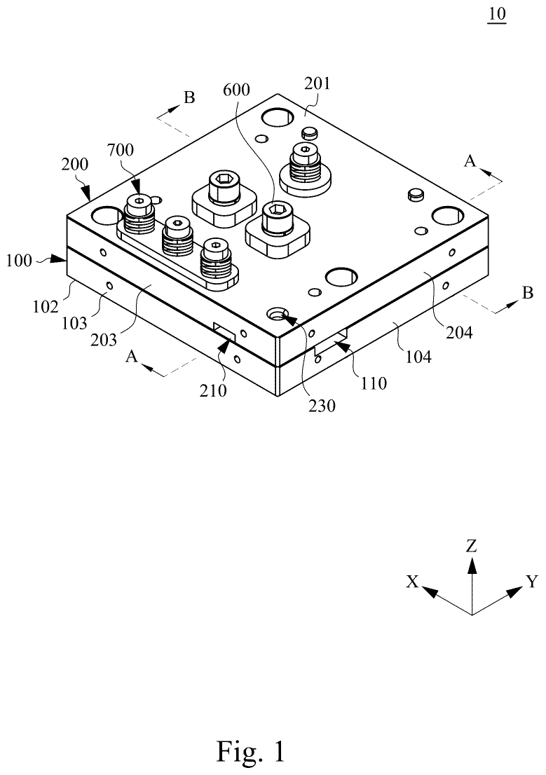

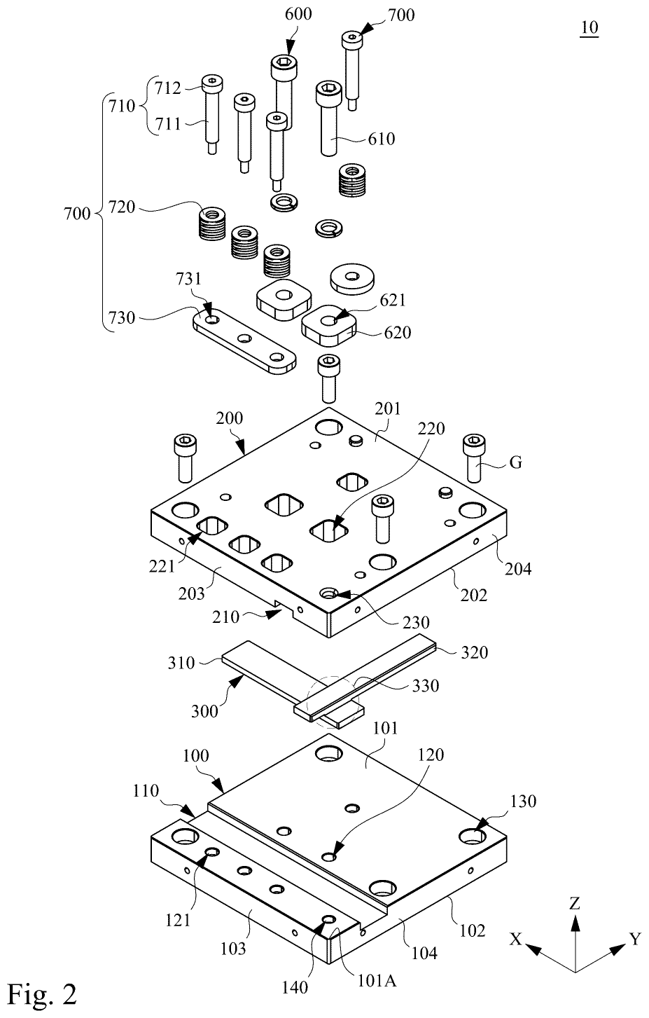

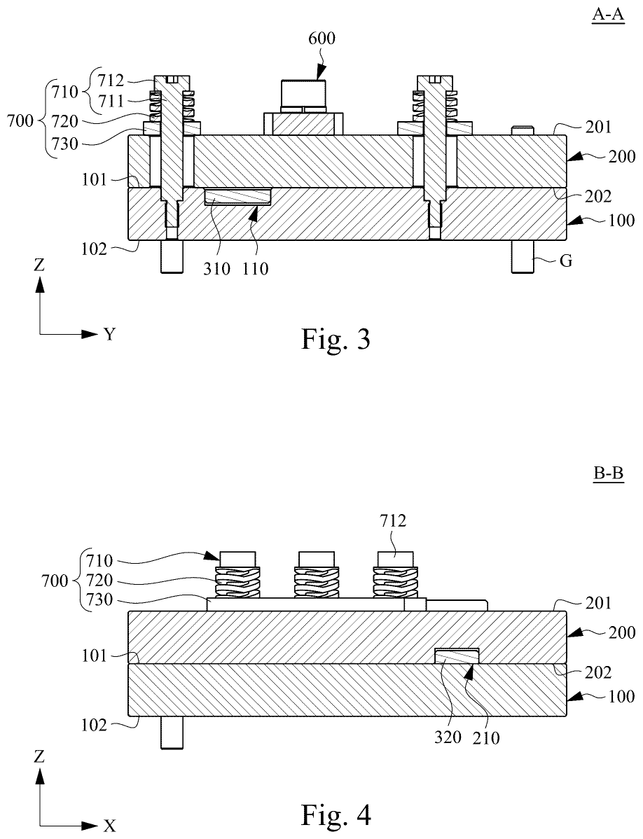

FIG. 1 is a perspective view of a position fine-tuning structure 10 according to one embodiment of the present disclosure. FIG. 2 is an exploded view of the position fine-tuning structure 10 of FIG. 1. FIG. 3 is a cross-sectional view of the position fine-tuning structure 10 viewed along a line AA in FIG. 1. As shown in FIG. 1 to FIG. 3, the position fine-tuning structure 10 includes a first plate 100, a second plate 200 and a guide slider 300. The second plate 200 and the first plate 100 are directly stacked with each other in Z axis, and the second plate 200 is slidably located on the first plate 100 so as to be moved for adjusting its position on the first plate 100 along different vectors (e.g., X axis, Y axis), respectively. The guide slider is L-shaped or cross-shaped, and respectively embedded in both of the first plate 100 and the second plate 200 for linearly guiding the movement of the second plate 200.

Furthermore, the first plate 100 includes a first top surface 101, a first bottom surface 102 and a plurality of first lateral surfaces (refer to a first front lateral surface 103 and a first side lateral surface 104, FIG. 2). The first top surface 101 and the first bottom surface 102 are opposite to each other, and the first lateral surfaces collectively surround the first top surface 101 and the first bottom surface 102, and two adjacent ones of the first lateral surfaces are the first front lateral surface 103 and the first side lateral surface 104, for example. The second plate 200 includes a second top surface 201, a second bottom surface 202 and a plurality of second lateral surfaces (refer to a second front lateral surface 203 and a second side lateral surface 204, FIG. 2). The second top surface 201 and the second bottom surface 202 are opposite to each other, and the second lateral surfaces collectively surround the second top surface 201 and the second bottom surface 202, and two adjacent ones of the second lateral surfaces are the second front lateral surface 203 and the second side lateral surface 204, for example. The second front lateral surface 203 and the first front lateral surface 103 both face towards a common direction (e.g., X axis), and the second side lateral surface 204 and the first side lateral surface 104 both face towards another common direction.

A first top surface 101 of the first plate 100 is recessed with a first linear groove 110. A second bottom surface 202 of the second plate 200 is recessed with a second linear groove 210. The second linear groove 210 is orthogonal to and in communication with the first linear groove 110, that is, a long axis direction (e.g., Y axis) of the second linear groove 210 and a long axis direction (e.g., X axis) of the first linear groove 110 are orthogonal to each other. The second bottom surface 202 of the second plate 200 directly covers the first top surface 101 of the first plate 100 so that the second linear groove 210 overlaps the first linear groove 110, and in communication with the first linear groove 110.

FIG. 4 is a cross-sectional view of the position fine-tuning structure 10 viewed along a line BB in FIG. 1. As shown in FIG. 2 and FIG. 4, the guide slider 300 includes a first pillar 310 and a second pillar 320. The second pillar 320 is integrally connected to, and orthogonal to the first pillar 310, that is, a long axis direction (e.g., X axis) of the first pillar 310 and a long axis direction (e.g., Y axis) of the second pillar 320 are orthogonal to each other. In the embodiment, the first pillar 310 and the second pillar 320 extend linearly, respectively, and the second pillar 320 is overlapped (or contacted) with one part of the first pillar 310. The first pillar 310 of the guide slider 300 is parallel to the first linear groove 110, and slidably received within the first linear groove 110 (FIG. 3). The second pillar 320 is parallel to the second linear groove 210, and slidably received within the second linear groove 210 (FIG. 4).

In the embodiment, more specifically, as shown in FIG. 2 and FIG. 3, the first plate 100 and the second plate 200 are respectively rectangular plates, and one part 330 of the second pillar 320 directly overlapped (or contacted) with the first pillar 310 is adjacent to one of corners 101A of the first plate 100.

In the embodiment, as shown in FIG. 2 and FIG. 3, the position fine-tuning structure 10 further includes two locking members 600. Each of the locking members 600 is fixedly connected to the first plate 100 and the second plate 200 so that the guide slider 300 is tightly clamped between the first plate 100 and the second plate 200. For example, each of the locking members 600 includes a first screw rod 610 and a gasket 620. The gasket 620 is located on the second top surface 201 of the second plate 200. The first screw rod 610 extends through a piercing hole 621 of the gasket 620, a piercing hole 220 of the second plate 200 and a piercing hole 120 of the first plate 100 in order so that the first plate 100 and the second plate 200 are tightly connected to each other.

In the embodiment, as shown in FIG. 1 and FIG. 4, the position fine-tuning structure 10 further includes a pressing member 700. The pressing member 700 is used to press the second plate 200 onto the first plate 100. More specifically, the pressing member 700 includes a plurality of second screw rods 710, a plurality of compression spring 720 and a pressing pad 730. Each of the second screw rods 710 includes a rod body 711 and a screw head 712. The screw head 712 is fixedly connected to one end of the rod body 711. The pressing pad 730 is located on the second top surface 201 of the second plate 200. The second screw rods 710 are spaced arranged on the pressing pad 730. The rod body 711 of each of the second screw rods 710 extends through one of the compression spring 720, a piercing hole 731 of the pressing pad 730, a piercing hole 221 of the second plate 200 and a piercing hole 121 of the first plate 100 in order. Each of the compression spring 720 respectively abuts against the screw head 712 of the second screw rod 710 and the second plate 200 for pushing the second plate 200 toward the first plate 100.

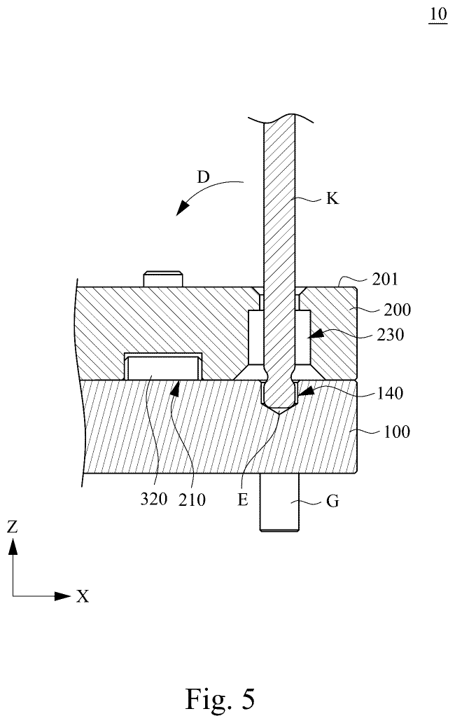

FIG. 5 is an operation schematic view of the position fine-tuning structure 10 of this embodiment. In the embodiment, as shown in FIG. 2 and FIG. 5, the first plate 100 includes a plurality of screw holes 130 and a plurality of locking pins G. The screw holes 130 are spaced distributed on the first plate 100. Thus, through the locking pins G being respectively inserted into the screw holes 130, the first plate 100 is able to be fixed on a platform (not shown in Figures).

The first top surface 101 of the first plate 100 is formed with a blind hole 140. The second plate 200 is further formed with a through hole 230. The through hole 230 is penetrated through the second plate 200, and two opposite ends of the through hole 230 are connected to the first top surface 101 and the first bottom surface 102, respectively. One of the opposite ends of the through hole 230 is coaxially connected the blind hole 140. The through hole 230 is adjacent to the aforementioned corner 101A of the first plate 100 and the part 330 of the second pillar 320 directly overlapped (or contacted) with the first pillar 310.

In this way, the position fine-tuning structure 10 of this embodiment is used in various situations which the required location is determined by naked eyes of a user, so that the user can intuitively adjust the position of the second plate 200 on the first plate 100. For example, when a user is desired to fine adjust the position of the second plate 200 on the first plate 100, the user first fixes the first plate 100 on the flat form (not shown); next, the user loosens the above-mentioned locking members 600; next, the user inserts a wrench K into the through hole 230 and the blind hole 140 so as to abut against the blind hole 140 by one end E of the wrench K. Thus, when the user rotates the wrench K along the direction D while using the end E of the wrench K as a fulcrum, the wrench K is able to push the second plate 200 from an inner wall of the through hole 230, so that the second plate 200 can be linearly moved a certain distance (e.g., several millimeters) along X axis (or Y axis) on the first plate 100 so as to complete a position fine adjustment (called as a major fine adjustment).

It is noted, since the guide slider 300 is suitably embedded within the first linear groove 110 and the second linear groove 210, if the user synchronously pushes the second plate 200 and the guide slider 300 along X axis by the wrench K, the second plate 200 can only be linearly moved along X axis due to the first pillar 310 being guided by the first linear groove 110. On the other hand, if the user synchronously pushes the second plate 200 and the guide slider 300 along the Y axis by the wrench K, the second plate 200 can only be linearly moved along the Y axis due to the second pillar 320 being guided by the second linear groove 210.

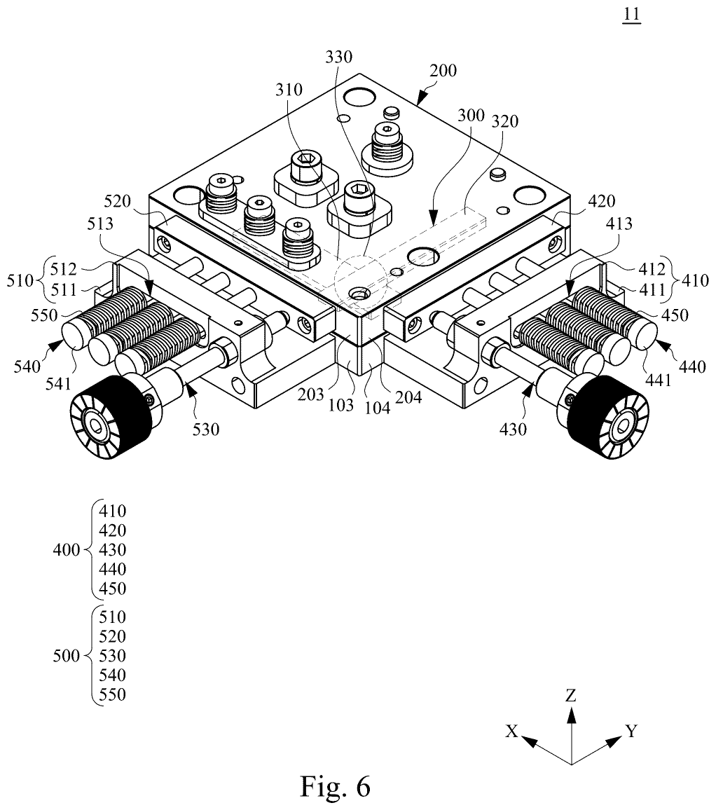

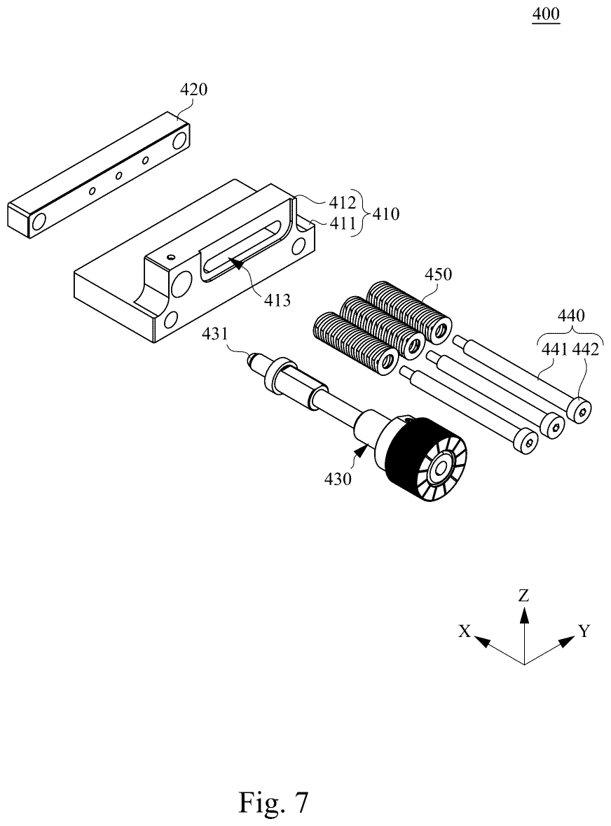

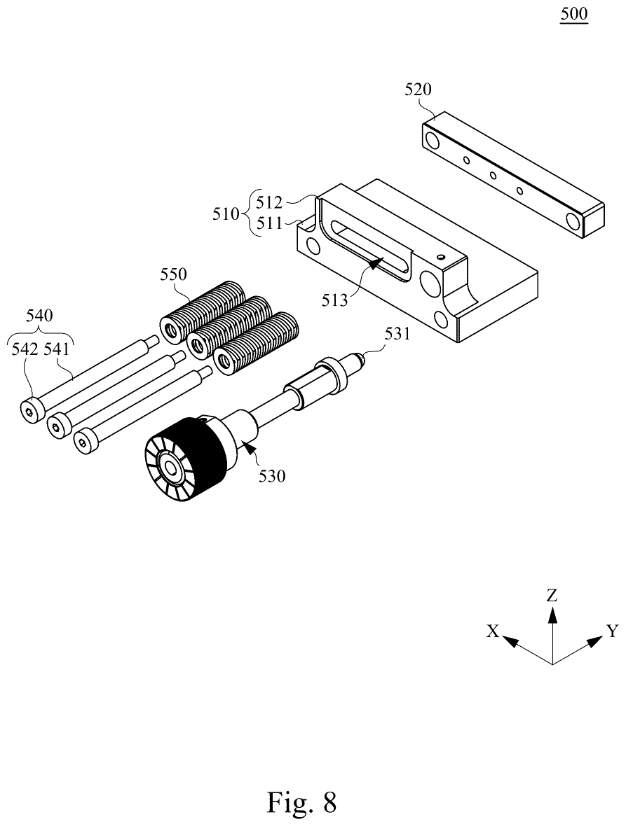

FIG. 6 is a perspective view of a position fine-tuning structure 11 according to one embodiment of the present disclosure. FIG. 7 is an exploded view of a first fine nudge module 400 of FIG. 6. FIG. 8 is an exploded view of a second fine nudge module 500 of FIG. 6. As shown in FIG. 6 to FIG. 8, the position fine-tuning structure 11 of the embodiment is substantially the same to the position fine-tuning structure 10 of FIG. 1, except that the position fine-tuning structure 11 further includes a first fine nudge module 400 and a second fine nudge module 500. Position adjustments of the second plate 200 on the first plate 100 along different vectors (e.g., X axis, Y axis) can be performed by one of the first fine nudge module 400 and the second fine nudge module 500. The first fine nudge module 400 is fixedly connected to the first side lateral surface 104 of the first plate 100 for relatively moving the second plate 200 on the first plate 100 along X axis. The second fine nudge module 500 is fixedly connected to the first front lateral surface 103 of the first plate 100 for relatively moving the second plate 200 on the first plate 100 along Y axis.

As shown in FIG. 6 and FIG. 7, more specifically, the first fine nudge module 400 includes a first loading base 410, a first pushing block 420 and a first pressing screw 430. The first loading base 410 is fixedly connected to the first side lateral surface 104 of the first plate 100. The first pushing block 420 is fixedly connected to the second side lateral surface 204 of the second plate 200. The first pressing screw 430 is screwedly mounted on the first loading base 410 and detachably connected to the first pushing block 420.

Furthermore, the first fine nudge module 400 further includes a plurality of first fixing studs 440 and a plurality of first springs 450. The first fixing studs 440 are spaced abreast with each other. Each of the first fixing studs 440 is disposed on the first loading base 410 and fixedly connected to the first pushing block 420. Each of the first springs 450 is sleeved on one of the first fixing studs 440 and abutted against the first loading base 410 and the first fixed stud 440, respectively.

The first loading base 410 includes a first base 411 and a first flange 412. The first base 411 is fixedly mounted on the first side lateral surface 104 of the first plate 100. The first flange 412 is protruded from the first base 411 and formed with a first elongated hole 413 thereon. The first pressing screw 430 penetrates through the first flange 412, and the first pressing screw 430 is screwedly installed on the first flange 412. One end 431 of the first pressing screw 430 is detachably abutted against the first pushing block 420. These first fixing studs 440 respectively pass through the first elongated hole 413 and fixedly connected to the first pushing block 420. Each of the first fixing studs 440 includes a first body 441 and a bolt head 442. The first body 441 is located within the first elongated hole 413, and the bolt head 442 is located at one end of the first body 441, and the other end of the first body 441 is fixedly connected to the first pushing block 420. Each of the first springs 450 is sleeved on one of the first bodies 441 and abuts against the first flange 412 and the bolt head 442 of the corresponding first fixing stud 440, respectively.

In this way, the position fine-tuning structure 11 of this embodiment is used in various situations in which require precise location control, so that the user can adjust the position of the second plate 200 on the first plate 100 through the fine-tuning screws. For example, when a user is desired to fine adjust the position of the second plate 200 by pushing the second plate 200 on the first plate 100 along X axis, the user screws the first pressing screw 430, so that the first pressing screw 430 being screwed begins to gradually approach and push the first pushing block 420 along X axis. Thus, the first pressing screw 430 linearly pushes against the second plate 200 to move a certain distance (e.g., several micrometers) on the first plate 100 through the first pushing block 420 so as to complete another position fine adjustment (called as a minor position fine adjustment). At this moment, the bolt head 442 and the first flange 412 jointly compress the first springs 450, so that the first spring 450 generates a restoring elastic force. On the contrary, when the user is desired to pull the second plate 200 back on the first plate 100 along X axis, the user screws the first pressing screw 430, so that the first pressing screw 430 being screwed begins to gradually retreat and moves away from the first pushing block 420 along X axis. At this moment, the restoring elastic force of the first spring 450 gradually pulls the second plate 200 through the first pushing block 420.

It is noted, since an orthogonal projection of the first pressing screw 430 along X axis passes through the aforementioned part 330 of the second pillar 320 directly overlapped (or contacted) with the first pillar 310, the first pressing screw 430 can effortlessly push the second plate 200 so that the second plate 200 can be linearly moved along with the guide slider 300 more smoothly.

As shown in FIG. 6 and FIG. 8, more specifically, the second fine nudge module 500 includes a second loading base 510, a second pushing block 520 and a second pressing screw 530. The second loading base 510 is fixedly connected to the first front lateral surface 103 of the first plate 100. The second pushing block 520 is fixedly connected to the second front lateral surface 203 of the second plate 200. The second pressing screw 530 is screwedly mounted on the second loading base 510 and detachably connected to the second pushing block 520.

Furthermore, the second fine nudge module 500 further includes a plurality of second fixing studs 540 and a plurality of second springs 550. The second fixing studs 540 are spaced abreast with each other. Each of the second fixing studs 540 is disposed on the second loading base 510 and fixedly connected to the second pushing block 520. Each of the second springs 550 is sleeved on one of the second fixing studs 540 and respectively abutted against the second loading base 510 and the second fixed stud 540.

The second loading base 510 includes a second base 511 and a second flange 512. The second base 511 is fixedly mounted on the first front lateral surface 103 of the first plate 100. The second flange 512 is protruded from the second base 511 and formed with a second elongated hole 513 thereon. The second pressing screw 530 penetrates through the second flange 512, and the second pressing screw 530 is screwedly installed on the second flange 512. One end 531 of the second pressing screw 530 is detachably abutted against the second pushing block 520. These second fixing studs 540 respectively pass through the second elongated hole 513 and fixedly connected to the second pushing block 520. Each of the second fixing studs 540 includes a second body 541 and a bolt head 542. The second body 541 is located within the second elongated hole 513, and the bolt head 542 is located at one end of the second body 541, and the other end of the second body 541 is fixedly connected to the second pushing block 520. Each of the second springs 550 is sleeved on one of the second bodies 541 and abutted against the second flange 512 and the bolt head 542 of the corresponding second fixing stud 540, respectively.

For example, when a user is desired to fine adjust the position of the second plate 200 by pushing the second plate 200 on the first plate 100 along the Y axis, the user screws the second pressing screw 530, so that the second pressing screw 530 being screwed begins to gradually approach and push the second pushing block 520 along Y axis. Thus, the second pressing screw 530 linearly pushes against the second plate 200 to move a certain distance (e.g., several micrometers) on the first plate 100 through the second pushing block 520 so as to complete another position fine adjustment (called as a minor position fine adjustment). At this moment, the bolt head 542 and the second flange 512 jointly compress the second springs 550, so that the second spring 550 generates a restoring elastic force.

On the other hand, when the user is desired to pull the second plate 200 back on the first plate 100 along Y axis, the user screws the second pressing screw 530, so that the second pressing screw 530 being screwed begins to gradually retreat and moves away from the second pushing block 520 along Y axis. At this moment, the restoring elastic force of the second spring 550 gradually pulls the second plate 200 through the second pushing block 520.

In addition, since these first fixing studs 440 are arranged abreast in the first elongated hole 413 along Y axis, when the second fine nudge module 500 moves the second plate 200 along Y axis, these first fixing studs 440 can be relatively displaced within the first elongated hole 413 so as to avoid from being interfered by the first loading base 410. On the contrary, since these second fixing studs 540 are arranged abreast in the second elongated hole 513 along X axis, when the second fine nudge module 500 moves the second plate 200 along X axis, these second fixing studs 540 can be relatively displaced within the second elongated hole 513 so as to avoid from being interfered by the second loading base 510.

It is noted, since an orthogonal projection of the second pressing screw 530 along Y axis passes through the aforementioned part 330 of the second pillar 320 directly overlapped (or contacted) with the first pillar 310, the second pressing screw 530 can effortlessly push the second plate 200 so that the second plate 200 can be linearly moved along with the guide slider 300 more smoothly.

However, the present disclosure is not limited thereto, in other embodiments, the position fine-tuning structure 10 may only have the first fine nudge module 400 or the second fine nudge module 500; the first fine nudge module 400 may also omit the first springs 450 and the first fixing studs 440 described above; or the second fine nudge module 500 may also omit the second springs 550 and the second fixing studs 540 described above.

Thus, through the construction of the embodiments above, the position fine-tuning structure of this disclosure can choose to install a movable second plate stacked onto the first plate without using a regular rail structure, thereby reducing the overall volume and thickness. Also, through the guide slider of the position fine-tuning structure, the first plate and the second plate which are combined together will not be displaced due to gap problems.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A position fine-tuning structure, comprising:
a first plate formed with a top surface and a first linear groove recessed on the top surface;
a second plate formed with a bottom surface and a second linear groove recessed on the bottom surface, wherein the bottom surface of the second plate directly covers the top surface of the first plate so that the second linear groove is orthogonal to and in communication with the first linear groove; and
a guide slider comprising a first pillar and a second pillar, the first pillar overlapped with and orthogonal to the second pillar, and the first pillar that is parallel to the first linear groove and slidably located within the first linear groove, and the second pillar that is parallel to the second linear groove and slidably located within the second linear groove.

2. The position fine-tuning structure of claim 1, wherein the first plate and the second plate are respectively rectangular plates, and one part of the second pillar directly overlapped with the first pillar is adjacent to one of corners of the first plate.

3. The position fine-tuning structure of claim 2, wherein the top surface of the first plate is formed with a blind hole, the second plate is further formed with a through hole, one end of the through hole is connected to the bottom surface of the second plate, and the through hole is coaxially connected the blind hole,
wherein the through hole is adjacent to the part of the second pillar directly overlapped with the first pillar and the one of the corners of the first plate.

4. The position fine-tuning structure of claim 1, further comprising:
a locking member fixedly connected to the first plate and the second plate for clamping the guide slider between the first plate and the second plate.

5. The position fine-tuning structure of claim 1, further comprising:
a pressing member disposed on the second plate for pressing the second plate onto the first plate.

6. The position fine-tuning structure of claim 1, further comprising:
a first fine nudge module fixedly connected to a first lateral surface of the first plate for relatively moving the second plate on the first plate along a first long axis direction of the first linear groove; and
a second fine nudge module fixedly connected to a second lateral surface of the first plate adjacent to the first lateral surface of the first plate for relatively moving the second plate on the first plate along a second long axis direction of the second linear groove.

7. The position fine-tuning structure of claim 6, wherein the first fine nudge module comprises:
a first loading base fixedly connected to the first lateral surface of the first plate;
a first pushing block fixedly connected to a first lateral surface of the second plate, and the first lateral surface of the second plate and the first lateral surface of the first plate collectively facing towards a first common direction; and
a first pressing screw screwedly mounted on the first loading base and detachably connected to the first pushing block,
wherein when the first pressing screw is screwed to push the first pushing block along the first long axis direction of the first linear groove, the first pressing screw linearly pushes against the second plate through the first pushing block so that the second plate is allowed to be moved on the first plate.

8. The position fine-tuning structure of claim 7, wherein an orthogonal projection of the first pressing screw is extended through one part of the second pillar directly overlapped with the first pillar along the first long axis direction of the first linear groove.

9. The position fine-tuning structure of claim 7, wherein the first fine nudge module further comprises:
at least one first fixed stud disposed on the first loading base and fixedly connected to the first pushing block; and
at least one first spring sleeved on the at least one first fixed stud and respectively abutted against the first loading base and the at least one first fixed stud,
wherein when the first pressing screw pushes the second plate through the first pushing block, the first loading base compresses the at least one first spring so that the at least one first spring generates a restoring elastic force,
when the first pressing screw is screwed away from the first pushing block, the restoring elastic force of the at least one first spring linearly pulls the second plate through the first pushing block.

10. The position fine-tuning structure of claim 6, wherein the second fine nudge module comprises:
a second loading base fixedly connected to the second lateral surface of the first plate;
a second pushing block fixedly connected to a second lateral surface of the second plate adjacent to the first lateral surface of the second plate, and the second lateral surface of the second plate and the second lateral surface of the first plate collectively facing towards a second common direction; and
a second pressing screw screwedly mounted on the second loading base and detachably connected to the second pushing block,
wherein when the second pressing screw is screwed to push the second pushing block along the second long axis direction of the second linear groove, the second pressing screw linearly pushes against the second plate through the second pushing block so that the second plate is allowed to be moved on the first plate.

11. The position fine-tuning structure of claim 10, wherein an orthogonal projection of the second pressing screw is extended through one part of the second pillar directly overlapped with the first pillar along the second long axis direction of the second linear groove.

12. The position fine-tuning structure of claim 10, wherein the second fine nudge module further comprises:
at least one second fixed stud disposed on the second loading base and fixedly connected to the second pushing block; and
at least one second spring sleeved on the at least one second fixed stud and respectively abutted against the second loading base and the at least one second fixed stud,
wherein when the second pressing screw pushes the second plate through the second pushing block, the second loading base compresses the at least one second spring so that the at least one second spring generates a restoring elastic force,
when the second pressing screw is screwed away from the second pushing block, the restoring elastic force of the at least one second spring linearly pulls the second plate through the second pushing block.

13. A position fine-tuning structure, comprising:
a first plate that is recessed with a first linear groove thereon;
a second plate that is recessed with a second linear groove thereon,
wherein the second plate directly covers the first plate so that the second linear groove is orthogonal to and in communication with the first linear groove;
a guide slider that is L-shaped or cross-shaped and comprising a first pillar and a second pillar, the first pillar that is overlapped with and orthogonal to the second pillar and integrally connected to the second pillar, the first pillar that is parallel to the first linear groove and slidably located within the first linear groove, and the second pillar that is parallel to the second linear groove and slidably located within the second linear groove; and
a pressing member connected to the first plate and the second plate for pressing the second plate onto the first plate, and limited the guide slider in the first linear groove and the second linear groove.

14. The position fine-tuning structure of claim 13, wherein the second plate is further formed with a through hole penetrating through two opposite surfaces of the second plate, and one surface of the first plate facing towards the second plate is formed with a blind hole coaxially connected the through hole,
wherein the through hole is adjacent to one part of the second pillar directly overlapped with the first pillar.

15. The position fine-tuning structure of claim 13, further comprising:
a locking member fixedly connected to the first plate and the second plate for clamping the guide slider between the first plate and the second plate.

16. The position fine-tuning structure of claim 13, further comprising:
a first fine nudge module fixedly connected to a first lateral surface of the first plate for relatively moving the second plate on the first plate along a first long axis direction of the first linear groove; and
a second fine nudge module fixedly connected to a second lateral surface of the first plate adjacent to the first lateral surface of the first plate for relatively moving the second plate on the first plate along a second long axis direction of the second linear groove.

17. The position fine-tuning structure of claim 16, wherein the first fine nudge module comprises:
a first loading base fixedly connected to the first lateral surface of the first plate;
a first pushing block fixedly connected to a first lateral surface of the second plate, and the first lateral surface of the second plate and the first lateral surface of the first plate collectively facing towards a first common direction; and
a first pressing screw screwedly mounted on the first loading base and detachably connected to the first pushing block,
wherein when the first pressing screw is screwed to push the first pushing block along the first long axis direction of the first linear groove, the first pressing screw linearly pushes against the second plate through the first pushing block so that the second plate is allowed to be moved on the first plate.

18. The position fine-tuning structure of claim 17, wherein the first fine nudge module further comprises:
at least one first fixed stud disposed on the first loading base and fixedly connected to the first pushing block; and
at least one first spring sleeved on the at least one first fixed stud and respectively abutted against the first loading base and the at least one first fixed stud,
wherein when the first pressing screw pushes the second plate through the first pushing block, the first loading base compresses the at least one first spring so that the at least one first spring generates a restoring elastic force,
when the first pressing screw is screwed away from the first pushing block, the restoring elastic force of the at least one first spring linearly pulls the second plate through the first pushing block.

19. The position fine-tuning structure of claim 16, wherein the second fine nudge module comprises:
a second loading base fixedly connected to the second lateral surface of the first plate;
a second pushing block fixedly connected to a second lateral surface of the second plate adjacent to the first lateral surface of the second plate, and the second lateral surface of the second plate and the second lateral surface of the first plate collectively facing towards a second common direction; and
a second pressing screw screwedly mounted on the second loading base and detachably connected to the second pushing block,
wherein when the second pressing screw is screwed to push the second pushing block along the second long axis direction of the second linear groove, the second pressing screw linearly pushes against the second plate through the second pushing block so that the second plate is allowed to be moved on the first plate.

20. The position fine-tuning structure of claim 19, wherein the second fine nudge module further comprises:
at least one second fixed stud disposed on the second loading base and fixedly connected to the second pushing block; and
at least one second spring sleeved on the at least one second fixed stud and respectively abutted against the second loading base and the at least one second fixed stud,
wherein when the second pressing screw pushes the second plate through the second pushing block, the second loading base compresses the at least one second spring so that the at least one second spring generates a restoring elastic force,
when the second pressing screw is screwed away from the second pushing block, the restoring elastic force of the at least one second spring linearly pulls the second plate through the second pushing block.
